(19) United States
(12) Patent Application Publication
(10) Pub. No.: US 2025/0157962 A1
(43) Pub. Date: May 15, 2025

(54) SEMICONDUCTOR PACKAGE INCLUDING DUMMY PADS AND MANUFACTURING METHOD FOR THE SAME

(71) Applicant: SAMSUNG ELECTRONICS CO., LTD., SUWON-SI (KR)

(72) Inventors: HANSUNG RYU, Suwon-si (KR); JONGBEOM PARK, Suwon-si (KR); HASEOB SEONG, Suwon-si (KR); AE-NEE JANG, Suwon-si (KR); JEEHYUN JUNG, Suwon-si (KR)

(21) Appl. No.: 18/761,918

(22) Filed: Jul. 2, 2024

(30) Foreign Application Priority Data
Nov. 13, 2023 (KR) 10-2023-0156753

(51) Int. Cl. H01L 23/00; H01L 23/31; H01L 23/48; H01L 25/065; H10B 80/00

(52) U.S. Cl. CPC H01L 24/06; H01L 24/08; H01L 25/0657; H01L 23/3157; H01L 23/481; H01L 2224/06051; H01L 2224/06179; H01L 2224/06181; H01L 2224/06517; H01L 2224/08146; H01L 2225/06503; H10B 80/00

(57) ABSTRACT

A semiconductor package includes: a plurality of first semiconductor chips; a second semiconductor chip including a front surface and disposed on the plurality of first semiconductor chips, and wherein the second semiconductor chip further includes a first dummy pad located on a back surface thereof; and a third semiconductor chip including a front surface and disposed on the second semiconductor chip. The third semiconductor chip further includes a second dummy pad located on the front surface thereof. The first dummy pad is disposed on at least a part of a back surface edge region that is adjacent to a side surface of the second semiconductor chip. The second dummy pad is disposed on at least a part of a front surface edge region that is adjacent to a side surface of the third semiconductor chip. The first dummy pad and the second dummy pad are bonded to each other.

### CROSS-REFERENCE TO RELATED APPLICATION

This application claims priority under 35 U.S.C. § 119 to Korean Patent Application No. 10-2023-0156753, filed in the Korean Intellectual Property Office on Nov. 13, 2023, the disclosure of which is incorporated by reference herein in its entirety.

### TECHNICAL FIELD

The present inventive concept relates to a semiconductor package and a manufacturing method for the same, and more particularly, to a semiconductor package including dummy pads and a manufacturing method for the same.

### DISCUSSION OF THE RELATED ART

In the semiconductor industry, high bandwidth memory (HBM) may provide high bandwidth and low power consumption. Generally, in high bandwidth memory, a plurality of memory chips may be stacked in a vertical direction and may be connected to each other through through-silicon vias (TSVs).

Additionally, stacked memory chips of high bandwidth memory can be protected by being covered with a molding material. If a void occurs between the semiconductor chips and the molding material, various issues such as damage to the semiconductor chip, deterioration of thermal conductivity, deterioration of reliability, performance degradation, and deterioration of cycle-life may occur.

### SUMMARY OF THE INVENTION

According to an embodiment of the present inventive concept, a semiconductor package includes: a plurality of first semiconductor chips stacked on each other; a second semiconductor chip including a front surface and disposed on the plurality of first semiconductor chips, wherein the front surface of the second semiconductor chip faces the plurality of first semiconductor chips, and wherein the second semiconductor chip further includes a first dummy pad located on a back surface, opposite to the front surface, of the second semiconductor chip; and a third semiconductor chip including a front surface and disposed on the back surface of the second semiconductor chip, wherein the front surface of the third semiconductor chip faces the second semiconductor chip, wherein the third semiconductor chip further includes a second dummy pad located on the front surface of the third semiconductor chip, wherein the first dummy pad is disposed on at least a part of a back surface edge region that is adjacent to a side surface of the second semiconductor chip, wherein the second dummy pad is disposed on at least a part of a front surface edge region that is adjacent to a side surface of the third semiconductor chip, and wherein the first dummy pad and the second dummy pad are bonded to each other.

According to an embodiment of the present inventive concept, a semiconductor package includes: a first semiconductor chip including a first dummy pad located on a back surface thereof; and a plurality of second semiconductor chips disposed on a back surface of the first semiconductor chip so that each front surface of each of the plurality of second semiconductor chips faces the first semiconductor chip, wherein a lowermost second semiconductor chip, which is disposed at the lowest position among the plurality of second semiconductor chips, includes a second dummy pad located on the front surface of the second semiconductor chip, wherein the second dummy pad is disposed on at least a part of a front surface edge region that is adjacent to a side surface of the lowermost second semiconductor chip, and wherein the first dummy pad is bonded to the second dummy pad by overlapping each other.

According to an embodiment of the present inventive concept, a semiconductor package includes: a first semiconductor chip having opposing front and back surfaces, and including a first connection pad located on the front surface thereof, a second connection pad and a first dummy pad located on the back surface thereof and spaced apart from each other, and a first through via electrically connecting the first connection pad and the second connection pad to each other; and a second semiconductor chip including a front surface and disposed on the back surface of the first semiconductor chip, wherein the front surface of the second semiconductor chip faces the first semiconductor chip, and wherein the second semiconductor chip further includes a third connection pad and a second dummy pad spaced apart from each other on the front surface of the second semiconductor chip, wherein the first dummy pad is disposed on at least a part of a back surface edge region that is adjacent to a side surface of the first semiconductor chip, wherein the second dummy pad is disposed on at least a part of a front surface edge region that is adjacent to a side surface of the second semiconductor chip, wherein the first dummy pad and the second dummy pad are bonded to each other, and wherein the second connection pad and the third connection pad are bonded to each other.

### BRIEF DESCRIPTION OF THE DRAWINGS

FIG. 1 is a cross-sectional view of a semiconductor package according to an embodiment of the present inventive concept.

FIGS. 2, 3 and 4 are diagrams illustrating issues that may occur in a semiconductor package that does not include a dummy pad according to a comparative example.

FIG. 5 illustrates a form of a first dummy pad according to an embodiment of the present inventive concept.

FIG. 6 illustrates a form of a second dummy pad according to an embodiment of the present inventive concept.

FIG. 7 illustrates a form of the first dummy pad according to an embodiment of the present inventive concept.

FIG. 8 illustrates a form of the second dummy pad according to an embodiment of the present inventive concept.

FIG. 9 illustrates a form of the first dummy pad according to an embodiment of the present inventive concept.

FIG. 10 illustrates a form of the second dummy pad according to an embodiment of the present inventive concept.

FIG. 11 illustrates a form of the first dummy pad according to an embodiment of the present inventive concept.

FIG. 12 illustrates a form of the second dummy pad according to an embodiment of the present inventive concept.

FIG. 13 illustrates a form of the first dummy pad according to an embodiment of the present inventive concept.

FIG. 14 illustrates a form of the second dummy pad according to an embodiment of the present inventive concept.

FIG. 15 is a cross-sectional view of a semiconductor package according to an embodiment of the present inventive concept.

FIG. 16 is a cross-sectional view of a semiconductor package according to an embodiment of the present inventive concept.

### DETAILED DESCRIPTION OF THE EMBODIMENTS

Hereinafter, embodiments of the present inventive concept will be described in detail hereinafter with reference to the accompanying drawings. As those skilled in the art would realize, the described embodiments may be modified in various different ways, all without departing from the spirit or scope of the present inventive concept.

The drawings and description are to be regarded as illustrative in nature and not restrictive. Like reference numerals designate like elements throughout the specification, and thus, redundant descriptions may be omitted or briefly discussed.

In the drawings, various thicknesses, lengths, and angles are shown and while the arrangement shown does indeed represent an embodiment of the present inventive concept, it is to be understood that modifications of the various thicknesses, lengths, and angles may be possible within the spirit and scope of the present inventive concept and the present inventive concept is not necessarily limited to the particular thicknesses, lengths, and angles shown.

It will be understood that when an element is referred to as being “connected” or “coupled” to another element, the element may be directly connected or coupled to the other element or intervening elements. In a similar perspective, this includes cases where it is “physically coupled” and cases where it is “electrically coupled.”

It will be understood that when an element such as a layer, film, region, or substrate is referred to as being “on” another element, it can be directly on the other element or intervening elements may also be present. In contrast, when an element is referred to as being “directly on” another element, there are no intervening elements present therebetween.

In addition, spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, in the example, terms “below” and “beneath” may encompass both an orientation of above, below and beneath. The device may be otherwise oriented (e.g., rotated 90 degrees or at other orientations) and the spatially relative descriptors used herein may be interpreted accordingly.

In addition, the phrase “on a plane” means a view from a position above the object (e.g., from the top), and the phrase “on a cross-section” means a view of a cross-section of the object which is vertically cut from the side.

In addition, throughout the specification, although terms of “first,” “second,” and the like are used to explain various constituent elements, the constituent elements are not limited to such terms. These terms are only used to distinguish one constituent element from another constituent element. Accordingly, a configuration referred to as the first constituent element in a certain part of the specification may also be referred to as the second constituent element in other parts of the specification. Further, the constituent elements referred to herein as first constituent elements may be the same as each other, but may also be similar constituent elements.

As used herein, the singular forms are intended to include the plural forms unless the context clearly indicates otherwise. For example, “insulating layer” may be used to mean not just a single insulating layer, but a plurality of insulating layers, such as two, three, or more. Hereinafter, a semiconductor package according to embodiments of the present inventive concept will be described with reference to the drawings.

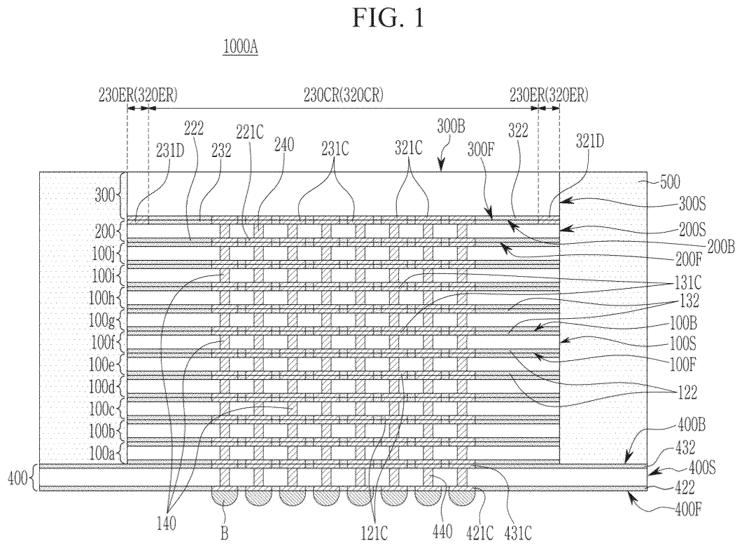

FIG. 1 is a cross-sectional view of a semiconductor package according to an embodiment of the present inventive concept.

A semiconductor package 1000A according to an embodiment of the present inventive concept may include a plurality of stacked first semiconductor chips 100, second semiconductor chips 200, third semiconductor chips 300, fourth semiconductor chips 400, and a molding material 500.

Each of the first semiconductor chip 100, the second semiconductor chip 200, the third semiconductor chip 300, and the fourth semiconductor chip 400 may have front and back surfaces (or, e.g., upper and lower surfaces) that are opposite to each other. For example, general components of a semiconductor chip, such as a semiconductor substrate, a plurality of individual devices, a wiring layer, and an interlayer insulating layer, may be disposed between the front and back surfaces of each semiconductor chip 100, 200, 300, and 400.

The plurality of first semiconductor chips 100 may be stacked on each other. For example, the plurality of first semiconductor chips 100 may be disposed such that a front surface 100F of each first semiconductor chip 100, except the lowermost first semiconductor chip 100, faces a back surface 100B of another adjacent first semiconductor chip 100. For example, a front surface 100F of the lowermost first semiconductor chip 100 faces a back surface 400B of a fourth semiconductor chip 400, which is stacked below the lowermost first semiconductor chip 100.

Each of the plurality of first semiconductor chips 100 may include a first connection pad 121C located at the front surface 100F, a first insulating layer 122 disposed on a side surface of a first connection pad 121C, a second connection pad 131C located at the back surface 100B, a second insulating layer 132 disposed on a side surface of a second connection pad 131C, and a first through via 140 electrically connecting the first connection pad 121C and the second connection pad 131C to each other.

Each of the first connection pad 121C and the second connection pad 131C may be made of a conductive material, for example, a metal such as copper or aluminum, or an alloy of metals.

Further, an insulating material may be used as the material for each of the first insulating layer 122 and the second insulating layer 132. For example, the insulating material may include silicon oxide, silicon nitride, and the like.

A conductive material such as copper or aluminum may be used as a material for the first through via 140, and an insulating barrier layer may be disposed on the side surface of the first through via 140.

For example, the plurality of first semiconductor chips 100 may be hybrid-bonded to each other. During hybrid bonding, the first connection pad 121C and the second connection pad 131C of the two first semiconductor chips 100 that face each other among the plurality of first semiconductor chips 100 may be directly bonded to each other. Further, the first insulating layer 122 and the second insulating layer 132 of two first semiconductor chips 100 of the plurality of first semiconductor chips 100 facing each other may be directly bonded to each other. In this specification, certain components being “directly bonded” means that they are physically in contact and bonded with each other.

Hybrid bonding may have beneficial effects such as reduced pitch between connection pads, increased bandwidth, increased power capacity, and reduced thermal resistance. Each of the plurality of first semiconductor chips 100 may be a high bandwidth memory chip for configuring a high bandwidth memory (HBM) package. In the technical field to which the present inventive concept pertains, the first semiconductor chip 100 may be referred to as, for example, a core chip, a slave chip, and the like.

The number of the plurality of first semiconductor chips 100 is not particularly limited, and there may be more or fewer first semiconductor chips 100 than shown in FIG. 1.

The second semiconductor chip 200 may be disposed on the plurality of first semiconductor chips 100 so that the front surface 200F faces the plurality of first semiconductor chips 100.

The second semiconductor chip 200 may include a third connection pad 221C located on the front surface 200F, a third insulating layer 222 disposed on the side surface of the third connection pad 221C, a first dummy pad 231D located on the back surface 200B, a fourth connection pad 231C spaced apart from the first dummy pad 231D on the back surface 200B, a fourth insulating layer 232 disposed on the side surfaces of the first dummy pad 231D and the fourth connection pad 231C, and a second through via 240 electrically connecting the third connection pad 221C and the fourth connection pad 231C to each other.

A conductive material may be used as the material for each of the third connection pad 221C, the first dummy pad 231D, and the fourth connection pad 231C, and for example, the conductive material may include a metal such as copper or aluminum or an alloy of metals may be used.

Additionally, an insulating material may be used as the material for each of the third insulating layer 222 and the fourth insulating layer 232, and for example, the insulating material may include silicon oxide, silicon nitride, and the like.

A conductive material such as copper or aluminum may be used as a material for the second through via 240, and an insulating barrier layer may be disposed on the side surface of the second through via 240.

Depending on the need, the second semiconductor chip 200 might not include the second through via 240, which is a component for electrical connection with the first semiconductor chip 100, and the fourth connection pad 231C that is electrically connected to the second through via 240.

In this case, the third semiconductor chip 300 might not include a fifth connection pad 321C for connection to the fourth connection pad 231C.

For example, the second semiconductor chip 200 may be hybrid-bonded with a first semiconductor chip 100j disposed at the uppermost position among the plurality of first semiconductor chips 100. During hybrid bonding, the second connection pad 131C of the first semiconductor chip 100j disposed at the uppermost position of the plurality of first semiconductor chips 100 may be directly bonded with the third connection pad 221C of the second semiconductor chip 200. In addition, the second insulating layer 132 of the first semiconductor chip 100j disposed at the uppermost position of the plurality of first semiconductor chips 100 and the third insulating layer 222 of the second semiconductor chip 200 may be directly bonded to each other.

The first dummy pad 231D may be disposed on at least a part of a back surface edge region 230ER adjacent to a side surface 200S of the second semiconductor chip 200. Here, the back surface edge region 230ER includes a region that is adjacent to the corner formed by the side surface 200S and the back surface 200B of the second semiconductor chip 200. Accordingly, the outer surface of the first dummy pad 231D may overlap the corner formed by the side surface 200S and the back surface 200B of the second semiconductor chip 200.

The width of the first dummy pad 231D may be about 50 μm to about 500 μm. For example, the width of the first dummy pad 231D refers to the distance measured in a direction perpendicular to the plane from the edge of the back surface of the second semiconductor chip 200, in other words, the corner formed by the side surface 200S and the back surface 200B of the second semiconductor chip 200. For example, the width of the first dummy pad 231D may extend in a direction parallel to back surface 200B.

If the width of the first dummy pad 231D is too narrow, alignment and bonding with the second dummy pad 321D may be difficult. Additionally, if the width of the first dummy pad 231D is too wide, the space for arranging other components of the second semiconductor chip 200, such as the fourth connection pad 231C, may be limited and the process time may be prolonged. Accordingly, it may be desirable to control the width of the first dummy pad 231D within the above-mentioned range.

Example shapes that the first dummy pad 231D may have will be described later.

On the other hand, the fourth connection pad 231C may be disposed in a center region 230CR surrounded by the back surface edge region 230ER of the second semiconductor chip 200.

The second semiconductor chip 200 may be a dummy chip sacrificed for bonding a third semiconductor chip 300, which will be described later. The third semiconductor chip 300 may be disposed on the plurality of first semiconductor chips 100 for the purposes of, for example, heat dissipation, warpage control, and physical, mechanical, and chemical protection of the plurality of first semiconductor chips 100. At this time, warpage may occur due to differences in coefficient of thermal expansion (CTE) between each component of the first semiconductor chips 100, and the adhesive surface of the first semiconductor chip 100 to be bonded to the third semiconductor chip 300 might not be smooth. Therefore, after attaching the second semiconductor chip 200, which is a sacrificial chip, on the first semiconductor chip 100 and planarizing the back surface 200B of the second semiconductor chip 200 by grinding, the third semiconductor chip 300 may be bonded on the back surface 200B of the planarized second semiconductor chip 200.

The third semiconductor chip 300 may be disposed on the back surface 200B of the second semiconductor chip 200 so that the front surface 300F of the third semiconductor chip 300 faces the second semiconductor chip 200.

The third semiconductor chip 300 may include the second dummy pad 321D located on the front surface 300F, the fifth connection pad 321C located spaced apart from the second dummy pad 321D on the front surface 300F, and a fifth insulating layer 322 disposed on the side surfaces of the second dummy pad 321D and the fifth connection pad 321C.

Each of the second dummy pad 321D and the fifth connection pad 321C may be made of a conductive material, for example, a metal such as copper or aluminum, or an alloy of metals.

Additionally, an insulating material may be used as a material for the fifth insulating layer 322. For example, the insulating material may include silicon oxide and silicon nitride.

For example, the third semiconductor chip 300 may be hybrid-bonded with the second semiconductor chip 200. During hybrid bonding, the fourth connection pad 231C of the second semiconductor chip 200 and the fifth connection pad 321C of the third semiconductor chip 300 may be directly bonded to each other. Additionally, the fourth insulating layer 232 of the second semiconductor chip 200 and the fifth insulating layer 322 of the third semiconductor chip 300 may be directly bonded to each other.

The second dummy pad 321D may be disposed on at least a part of a front surface edge region 320ER that is adjacent to a side surface 300S of the third semiconductor chip 300. Here, the front surface edge region 320ER includes a region that is adjacent to the corner formed by the side surface 300S and the front surface 300F of the third semiconductor chip 300. Accordingly, the outer surface of the second dummy pad 321D may overlap the corner formed by the side surface 300S and the front surface 300F of the third semiconductor chip 300.

The width of the second dummy pad 321D may also be about 50 μm to about 500 μm. The width of the second dummy pad 321D refers to the distance measured in a direction perpendicular to the plane from the edge of the front surface of the third semiconductor chip 300, in other words, the corner formed by the side surface 300S and the front surface 300F of the third semiconductor chip 300. For example, the width of the second dummy pad 231D may extend in a direction parallel to front surface 300F. If the width of the second dummy pad 321B is too narrow, alignment and bonding with the first dummy pad 231D may be difficult. Additionally, if the width of the second dummy pad 321B is too wide, the space for arranging other components of the third semiconductor chip 300, such as the fifth connection pad 321C, may be limited and the process time may be prolonged. Accordingly, it may be desirable to control the width of the second dummy pad 321B within the above-mentioned range.

Example shapes that the second dummy pad 321D may have will be described later.

On the other hand, the fifth connection pad 321C may be disposed in a center region 320CR that is surrounded by the front surface edge region 320ER of the third semiconductor chip 300.

The first dummy pad 231D of the second semiconductor chip 200 and the second dummy pad 321D of the third semiconductor chip 300 may be directly bonded to each other. The first dummy pad 231D of the second semiconductor chip 200 and the second dummy pad 321D of the third semiconductor chip 300 may overlap each other, and may have shapes corresponding to each other.

The third semiconductor chip 300 may be a dummy chip. As described above, the third semiconductor chip 300 may perform functions such as heat dissipation, warpage control, and physical, mechanical, and chemical protection of the plurality of first semiconductor chips 100.

In terms of heat dissipation and warpage control, the third semiconductor chip 300 may have a thick thickness. For example, the thickness of the third semiconductor chip 300 may be thicker than the thickness of the first semiconductor chip 100 and the second semiconductor chip 200, respectively.

The first semiconductor chip 100, the second semiconductor chip 200, and the third semiconductor chip 300 may be disposed on the fourth semiconductor chip 400.

The fourth semiconductor chip 400 may include a sixth connection pad 421C located on a front side 400F, a sixth insulating layer 422 disposed on a side surface of the sixth connection pad 421C, a seventh connection pad 431C located on a back surface 400B, a seventh insulating layer 432 disposed on a side surface of the seventh connection pad 431C, and a third through via 440 electrically connecting the sixth connection pad 421C and the seventh connection pad 431C to each other.

Each of the sixth connection pad 421C and the seventh connection pad 431C may be made of a conductive material, for example, a metal such as copper or aluminum, or an alloy of metals.

Additionally, each of the sixth insulating layer 422 and the seventh insulating layer 432 may include an insulating material, for example, silicon oxide, silicon nitride, and the like.

A conductive material such as copper or aluminum may be used as a material for the third through via 440, and an insulating barrier layer may be disposed on the side surface of the third through via 440.

For example, the fourth semiconductor chip 400 may be hybrid-bonded with a first semiconductor chip 100a disposed at the lowest position among the plurality of first semiconductor chips 100. During hybrid bonding, the first connection pad 121C of the first semiconductor chip 100a that is disposed at the lowest position of the plurality of first semiconductor chips 100 may be directly bonded with the seventh connection pad 431C of the fourth semiconductor chip 400. In addition, the first insulating layer 122 of the first semiconductor chip 100a, which is disposed at the lowest position of the plurality of first semiconductor chips 100, and the seventh insulating layer 432 of the fourth semiconductor chip 400 may be directly bonded to each other.

The fourth semiconductor chip 400 may be a logic chip for configuring a high bandwidth memory package. In the technical field to which the present invention pertains, the fourth semiconductor chip 400 may be referred to as, for example, a buffer chip, a base chip, etc.

The width of the fourth semiconductor chip 400 may be wider than the width of the first semiconductor chips 100. Here, the width refers to the distance between any two side surfaces facing each other.

A conductive bump B, such as a solder ball, may be disposed on the sixth connection pad 421C of the fourth semiconductor chip 400.

The molding material 500 may be disposed on the fourth semiconductor chip 400 to mold the plurality of first semiconductor chips 100, second semiconductor chip 200, and third semiconductor chip 300. For example, the molding material 500 may cover the plurality of first semiconductor chips 100, the second semiconductor chip 200, and third semiconductor chip 300. Depending on the need, the molding material 500 may mold the fourth semiconductor chip 400 together with the first semiconductor chip 100, the second semiconductor chip 200, and the third semiconductor chip 300.

The molding material 500 may cover side surfaces of each of the plurality of first semiconductor chips 100, the second semiconductor chip 200, and the third semiconductor chip 300. Accordingly, the molding material 500 may cover the outer surfaces of each of the first dummy pad 231D of the second semiconductor chip 200 and the second dummy pad 321D of the third semiconductor chip 300.

The back surface 300B of the third semiconductor chip 300 may be exposed from the molding material 500. For example, the back surface 300B of the third semiconductor chip 300 might not be covered by the molding material 500. When the back surface 300B of the third semiconductor chip 300 is exposed from the molding material 500, an increased heat dissipation effect may be achieved and the semiconductor package may be made thinner.

An insulating material may be used as a material for the molding material 500. For example, the insulating material may include epoxy mold compound (EMC), epoxy resin, and the like.

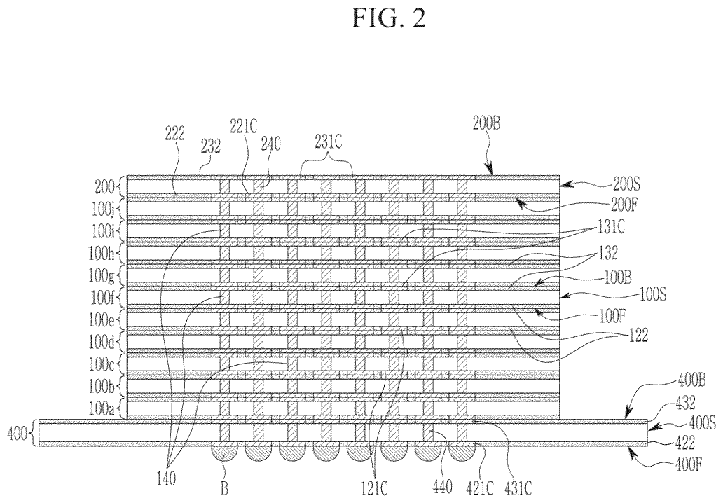

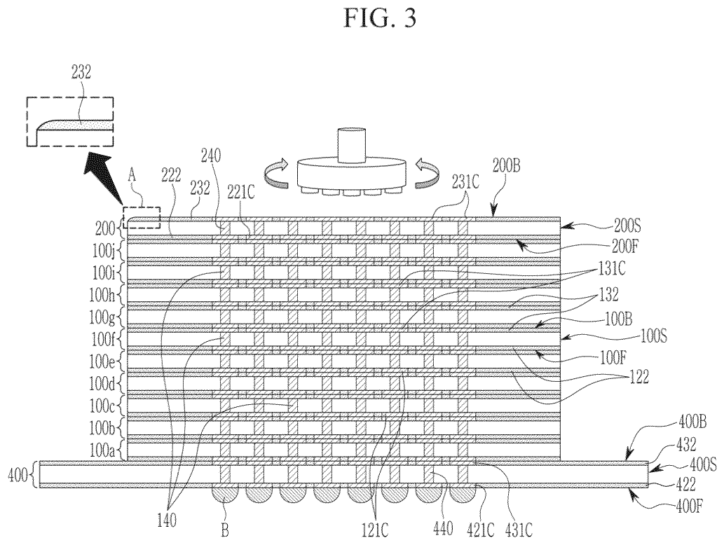

In addition, as shown in FIGS. 2 and 3, in the process of attaching a second the semiconductor chip 200 to the first semiconductor chip 100 and grinding the back surface 200B of the second semiconductor chip 200 to flatten the back surface 200B, the back surface edge region of the second semiconductor chip 200 may be processed to have a round shape. For example, an edge of the fourth insulating layer 232 may be rounded. This process may result in a phenomenon where the back surface edge region is located at a level that is lower than the central region of the second semiconductor chip 200.

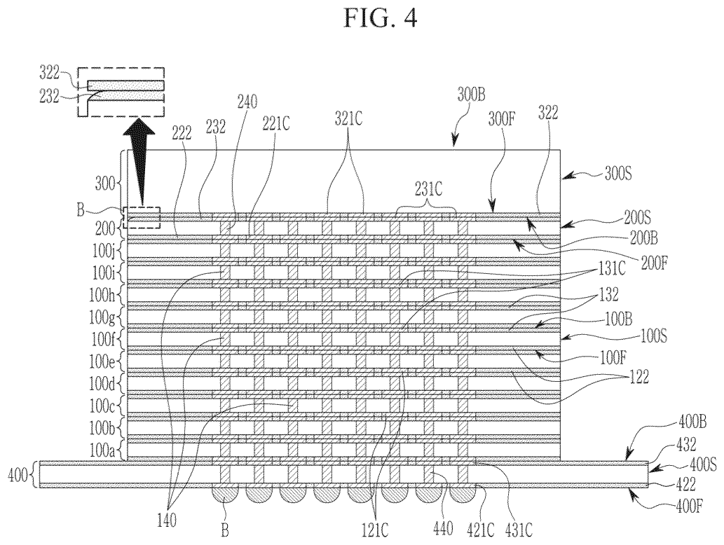

At this time, as shown in FIG. 4, the edge region of the second semiconductor chip 200 does not contact the third semiconductor chip 300 that is bonded to the back surface 200B of the second semiconductor chip 200, and a gap may exist between the second semiconductor chip 200 and the third semiconductor chip 300. Therefore, after molding the second semiconductor chip 200 and the third semiconductor chip 300 with the molding material 500, a void may occur between the edge region of the second semiconductor chip 200 and the third semiconductor chip 300.

A semiconductor package 1000A according to an embodiment of the present inventive concept has the first dummy pad 231D disposed on the back surface edge region 230ER of the second semiconductor chip 200, and has the second dummy pad 321D disposed on the front surface edge region 320ER of the third semiconductor chip 300, thereby preventing a gap from being formed between the edge region 230ER of the second semiconductor chip 200 and the front surface edge region 320ER of the third semiconductor chip 300, which may prevent the occurrence of voids during molding. According to an embodiment of the present inventive concept, even if the first dummy pad 231D is partially processed in the thickness direction when grinding the back surface 200B of the second semiconductor chip 200, the first dummy pad 231D may be slightly expanded in the annealing process for bonding the second semiconductor chip 200 and the third semiconductor chip 300 to each other, so that the first dummy pad 231D may be directly bonded with the second dummy pad 321D.

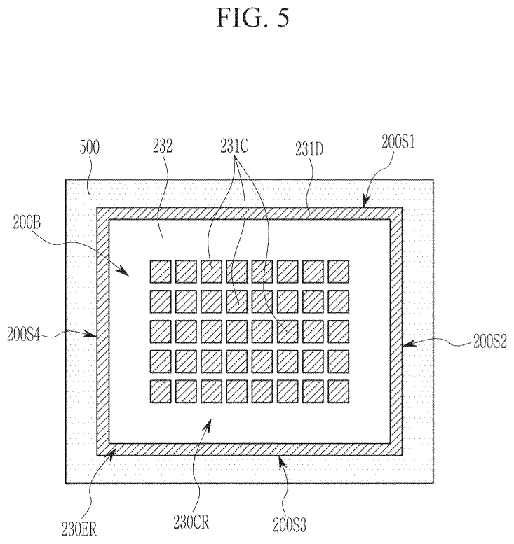

FIG. 5 illustrates a form of a first dummy pad according to an embodiment of the present inventive concept.

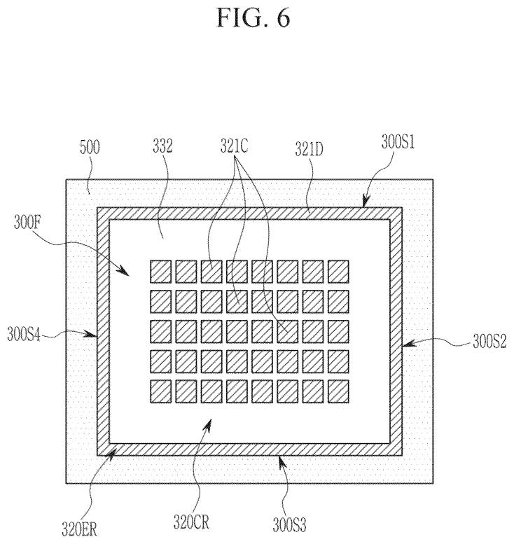

FIG. 6 illustrates a form of a second dummy pad according to an embodiment of the present inventive concept.

In an embodiment of the present inventive concept, the first dummy pads 231D may be continuously disposed along the back surface edge region 230ER of the second semiconductor chip 200. For example, the first dummy pad 231D may be disposed to extend along the region touching the corner formed by a first side surface 200S1 and the back surface 200B, the region touching the corner formed by a second side surface 200S2 and the back surface 200B, the region touching the corner formed by a third side surface 200S3 and the back surface 200B, and the region touching the corner formed by a fourth side surface 200S4 and the back surface 200B of the second semiconductor chip 200, so as to surround a central region 230CR of the back surface 200B of the second semiconductor chip 200.

Additionally, the second dummy pads 321D may be continuously disposed along the front surface edge region 320ER of the third semiconductor chip 300. For example, the second dummy pad 321D may be disposed to extend along the region touching the corner formed by a first side surface 300S1 and the front surface 300F, the region touching the corner formed by a second side surface 300S2 and the front surface 300F, the region touching the corner formed by a third side surface 300S3 and the front surface 300F, and the region touching the corner formed by a fourth side surface 300S4 and the front surface 300F of the third semiconductor chip 300, so as to surround a central region 320CR of the front surface 300F of the third semiconductor chip 300.

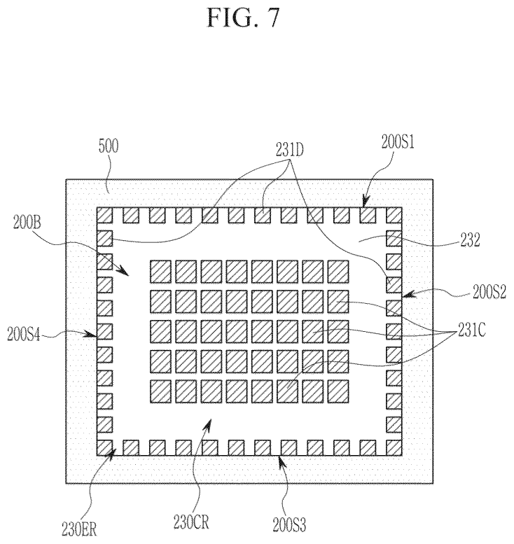

FIG. 7 illustrates a form of the first dummy pad according to an embodiment of the present inventive concept.

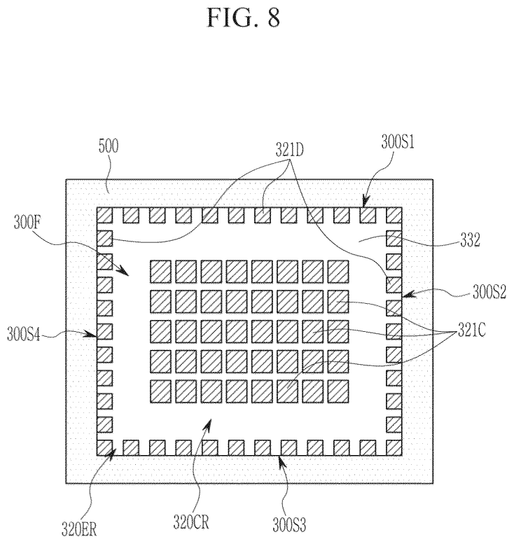

FIG. 8 illustrates a form of the second dummy pad according to an embodiment of the present inventive concept.

In an embodiment of the present inventive concept, the first dummy pads 231D may be discontinuously disposed along the back surface edge region 230ER of the second semiconductor chip 200. For example, a plurality of first dummy pads 231D may be arranged with a predetermined interval along the back surface edge region 230ER of the second semiconductor chip 200. Additionally, the second dummy pads 321D may be discontinuously disposed along the front surface edge region 320ER of the third semiconductor chip 300. For example, a plurality of second dummy pads 321D may be arranged with a predetermined interval along the front surface edge region 320ER of the third semiconductor chip 300.

It may be desirable that the discontinuously disposed first dummy pads 231D include the first dummy pads 231D respectively disposed in corner regions of the back surface edge region 230ER that are adjacent to the corners formed by the two side surfaces of the second semiconductor chip 200. In addition, it may be desirable that the discontinuously disposed second dummy pads 321D include the second dummy pads 321D respectively disposed in corner regions of the front surface edge region 320ER that are adjacent to the corners formed by the two side surfaces of the third semiconductor chip 300.

The width and interval of each of the discontinuously disposed first dummy pads 231D and second dummy pads 321D are not particularly limited and may vary depending on design.

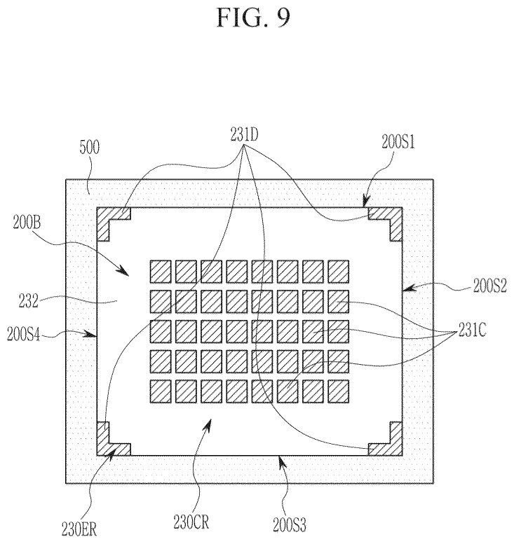

FIG. 9 illustrates a form of the first dummy pad according to an embodiment of the present inventive concept.

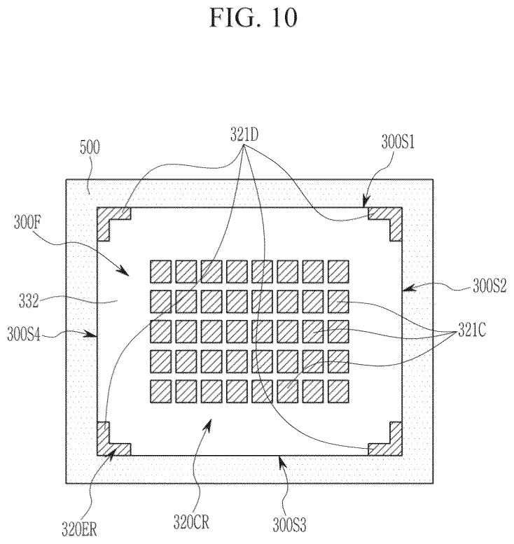

FIG. 10 illustrates a form of the second dummy pad according to an embodiment of the present inventive concept.

In an embodiment of the present inventive concept, the first dummy pad 231D may be disposed in a corner region, of the back surface edge region 230ER, adjacent to the corner formed by the two side surfaces of the second semiconductor chip 200. For example, the first dummy pads 231D may be respectively disposed in the back edge corner region adjacent to a corner formed by the first side surface 200S1 and the second side surface 200S2, a back edge corner region adjacent to a corner formed by the second side surface 200S2 and the third side surface 200S3, a back edge corner region adjacent to a corner formed by the third side surface 200S3 and the fourth side surface 200S4, and a back edge corner region adjacent to a corner formed by the fourth side surface 200S4 and the first side surface 200S1 of the second semiconductor chip 200.

Additionally, the second dummy pad 321D may be disposed in a corner region, of the front surface edge region 320ER, adjacent to the corner formed by the two side surfaces of the third semiconductor chip 300. For example, the second dummy pads 321D may be respectively disposed in front edge corner region adjacent to a corner formed by the first side surface 300S1 and the second side surface 300S2, a front edge corner region adjacent to a corner formed by the second side surface 300S2 and the third side surface 300S3, a front edge corner region adjacent to a corner formed by the third side surface 300S3 and the fourth side surface 300S4, and a front edge corner region adjacent to a corner formed by the fourth side surface 300S4 and the first side surface 300S1 of the third semiconductor chip 300.

In the drawing, the first dummy pads 231D and the second dummy pads 321D, which are disposed in each corner region, are shown as having an L-shape or a bent shape, but the present inventive concept is not limited thereto, and for example, each of the first dummy pads 231D and the second dummy pads 321D may have a square shape.

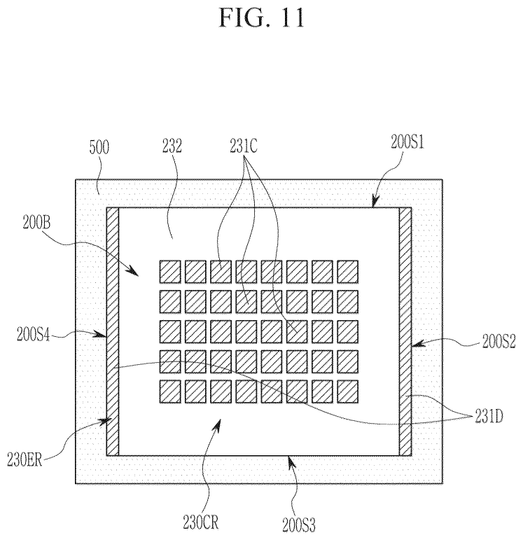

FIG. 11 illustrates a form of the first dummy pad according to an embodiment of the present inventive concept.

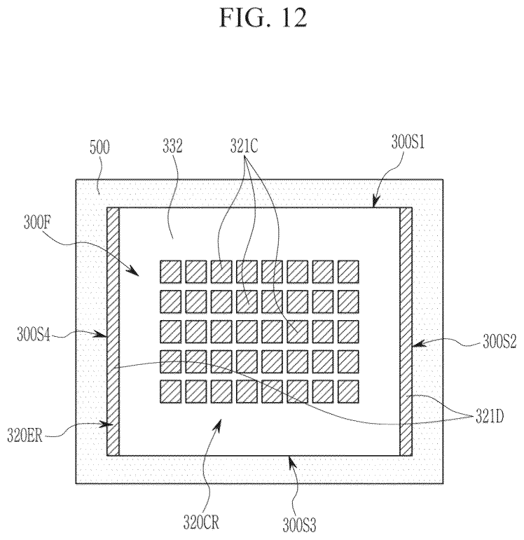

FIG. 12 illustrates a form of the second dummy pad according to an embodiment of the present inventive concept.

In an embodiment of the present inventive concept, the first dummy pads 231D may be continuously disposed along the regions adjacent to two side surfaces facing each other among the back surface edge region 230ER of the second semiconductor chip 200. For example, the first dummy pads 231D may be continuously disposed along the region adjacent to the second side surface 200S2 and the region adjacent to the fourth side surface 200S4 facing the second side surface 200S2 of the second semiconductor chip 200. For example, second side surface 200S2 and the fourth side surface 200S4 may each form a long side on a plane.

Additionally, the second dummy pads 321D may be continuously disposed along the regions adjacent to the two side surfaces facing each other among the front surface edge region 320ER of the third semiconductor chip 300. For example, the second dummy pads 321D may be continuously disposed along the region adjacent to the second side surface 300S2 and the region adjacent to the fourth side surface 300S4 facing the second side surface 300S2 of the third semiconductor chip 300. For example, each of the second side surface 300S2 and the fourth side surface 300S4 may form a long side on a plane.

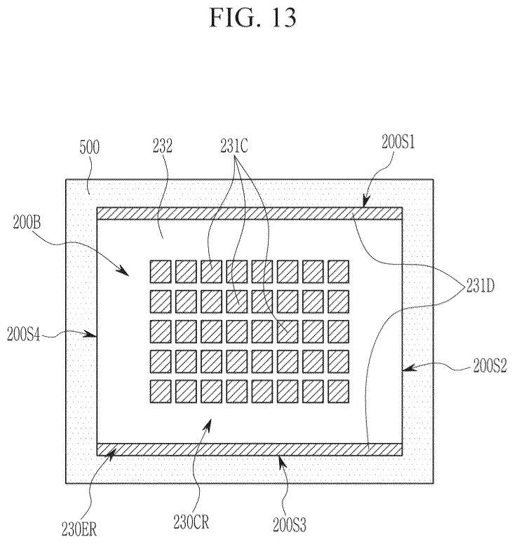

FIG. 13 illustrates a form of the first dummy pad according to an embodiment of the present inventive concept.

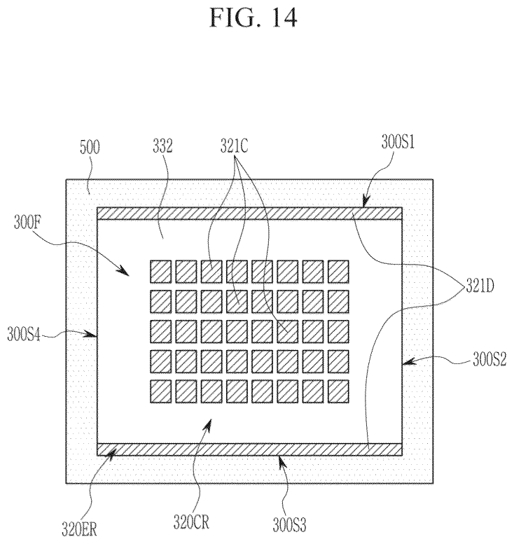

FIG. 14 illustrates a form of the second dummy pad according to an embodiment of the present inventive concept.

In an embodiment of the present inventive concept, the first dummy pad 231D may be continuously disposed along each of the regions adjacent to the first side surface 200S1 and the third side surface 200S3, which face each other, of the second semiconductor chip 200. For example, each of the first side surface 200S1 and the third side surface 200S3 may form a short side on a plane.

Additionally, the second dummy pad 321D may be continuously disposed along each of the regions adjacent to the first side surface 300S1 and the third side surface 300S3, which face each other, of the third semiconductor chip 300. For example, each of the first side surface 300S1 and the third side surface 300S3 may form a short side on a plane.

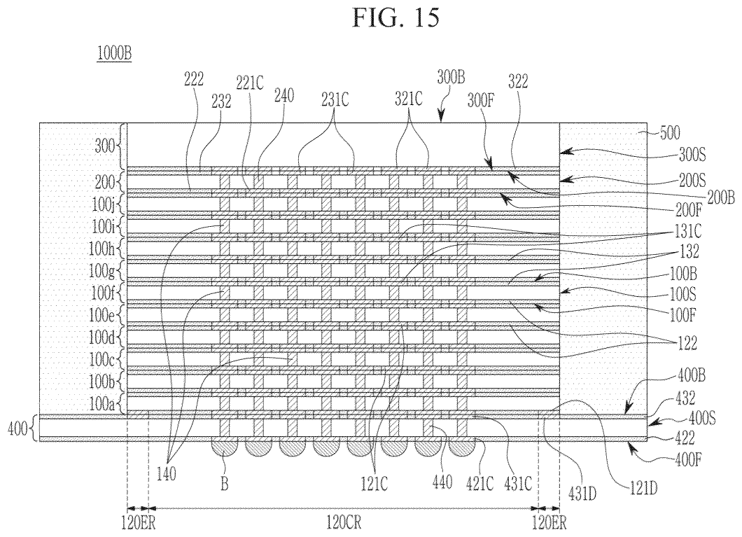

FIG. 15 is a cross-sectional view of a semiconductor package according to an embodiment of the present inventive concept.

In the case of a semiconductor package 1000B according to an embodiment of the present inventive concept, the first semiconductor chip 100a disposed on the lowest position among the plurality of first semiconductor chips 100 may include a third dummy pad 121D located on the front surface 100F, and the fourth semiconductor chip 400 may include a fourth dummy pad 431D located on the back surface 400B.

The third dummy pad 121D may be disposed on at least a part of a front surface edge region 120ER that is adjacent to a side surface 100S of the first semiconductor chip 100a.

The first connection pad 121C of the first semiconductor chip 100a may be located on the front surface 100F and spaced apart from the third dummy pad 121D. The first connection pad 121C may be disposed in a center region 120CR surrounded by the front surface edge region 120ER of the first semiconductor chip 100.

The third dummy pad 121D and the fourth dummy pad 431D may overlap each other on a plane and be directly bonded to each other. As described above, the width of the fourth semiconductor chip 400 may be wider than the width of the first semiconductor chip 100, and the fourth dummy pad 431D may be disposed in the center region rather than the edge region of the fourth semiconductor chip 400, to be bonded with the third dummy pad 121D.

Unless specifically contradicted, the descriptions for each of the above-described second dummy pad 321D and first dummy pad 231D are equally applicable to the description of each of the third dummy pad 121D and the fourth dummy pad 431D. For example, the third dummy pad 121D and the fourth dummy pad 431D may have one of the example shapes shown in FIGS. 5 to 14.

During the bonding of the first semiconductor chip 100a to the fourth semiconductor chip 400, due to the warpage of the first semiconductor chip 100a that has a thin thickness, a lifting phenomenon may occur between the front surface edge region 120ER of the first semiconductor chip 100a and the fourth semiconductor chip 400. According to an embodiment of the present inventive concept, a third dummy pad 121D is disposed on the front surface 100F of the first semiconductor chip 100a, and the fourth dummy pad 431D is disposed on the back surface 400B of the fourth semiconductor chip 400. Accordingly, it is possible to prevent a lifting phenomenon from occurring between the edge region 120ER of the first semiconductor chip 100a and the fourth semiconductor chip 400, thereby preventing voids from occurring during molding.

Depending on the need, the semiconductor package 1000B may additionally include the first dummy pad 231D and the second dummy pad 321D shown in FIG. 1.

Since the description of other components of the semiconductor package 1000B is the same as the description of the same or similar components specifically described in the description of the semiconductor package 1000A according to an embodiment of the present inventive concept, detailed description of these other components of the semiconductor package 1000B will be omitted to prevent redundant descriptions.

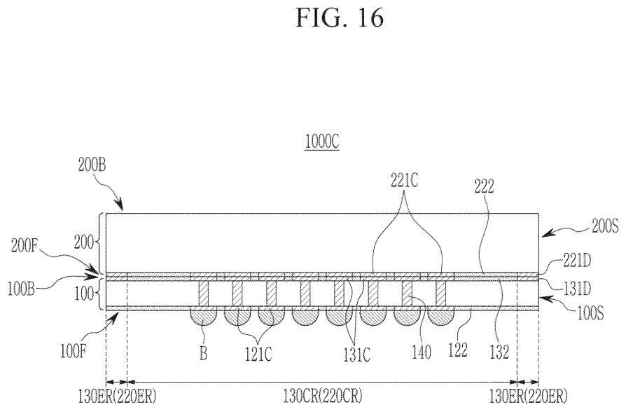

FIG. 16 is a cross-sectional view of a semiconductor package according to an embodiment of the present inventive concept.

The dummy pad according to embodiments of the present inventive concept may be applied in a variety of ways for purposes such as increased bonding between semiconductor chips and void prevention.

For example, a semiconductor package 1000C according to an embodiment of the present inventive concept may include the first semiconductor chip 100, which includes a fifth dummy pad 131D, and the second semiconductor chip 200, which includes a sixth dummy pad 221D.

Each of the first semiconductor chip 100 and the second semiconductor chip 200 may have front and back surfaces that are opposite to each other.

The first semiconductor chip 100 may include the first connection pad 121C located on the front surface 100F, the first insulating layer 122 located on a side surface of the first connection pad 121C, the second connection pad 131C, the fifth dummy pad 131D spaced apart from the second connection pad 131C on the back surface 100B, the second insulating layer 132 located on the side surface of the second connection pad 131C and the fifth dummy pad 131D, and the through via 140 electrically connecting the first connection pad 121C and the second connection pad 131C to each other.

The second semiconductor chip 200 may be disposed on the back surface 100B of the first semiconductor chip 100 so that the front surface 200F of the second semiconductor chip 200 faces the first semiconductor chip 100.

The second semiconductor chip 200 may include the third connection pad 221C, the sixth dummy pad 221D spaced apart from the third connection pad 221C on the front surface 200F, and the third insulating layer 222 located on the side surface of the third connection pad 221C and the sixth dummy pad 221D.

For example, the first semiconductor chip 100 and the second semiconductor chip 200 may be hybrid-bonded to each other. During hybrid bonding, the second connection pad 131C of the first semiconductor chip 100 and the third connection pad 221C of the second semiconductor chip 200 may be directly bonded to each other. Additionally, the second insulating layer 132 of the first semiconductor chip 100 and the third insulating layer 222 of the second semiconductor chip 200 may be directly bonded to each other.

The fifth dummy pad 131D may be disposed on at least a part of a back surface edge region 130ER that is adjacent to the side surface 100S of the first semiconductor chip 100, and the sixth dummy pad 221D may be disposed on at least a part of a front surface edge region 220ER that is adjacent to the side surface 200S of the second semiconductor chip 200. Additionally, the fifth dummy pad 131D and the sixth dummy pad 221D may be directly bonded to each other.

Unless specifically contradicted, the descriptions for each of the above-described first dummy pad 231D and the second dummy pad 321D are equally applicable to the description of each of the fifth dummy pad 131D and the sixth dummy pad 221D. For example, the fifth dummy pad 131D and the sixth dummy pad 221D may have one of the example shapes shown in FIGS. 5 to 14.

The types of each of the first semiconductor chip 100 and the second semiconductor chip 200 are not particularly limited, and may be, for example, a logic chip, a memory chip, or the like.

Depending on the need, the semiconductor package 1000C may further include components other than those shown in FIG. 16, for example, the molding material 500 for molding the first semiconductor chip 100 and the second semiconductor chip 200.

Since the description of other components of the semiconductor package 1000C is the same as the description of the same or similar components specifically described in the description of the semiconductor package 1000A according to an embodiment of the present inventive concept, detailed description of these other components of the semiconductor package 1000C will be omitted to prevent redundant descriptions.

While the present inventive concept has been shown and described with reference to the embodiments thereof, it will be apparent to those of ordinary skill in the art that various changes in form and detail may be made thereto without departing from the spirit and scope of the present inventive concept.

Additionally, the content described in the description of an embodiment of the present inventive concept may be equally applied to other embodiments of the present inventive concept even if it is not described in the description of the other embodiments unless there is a particular contradiction.

The embodiments of the present inventive concept may be combined with each other, and are not to be interpreted as being independent embodiments. A person of an ordinary skill in the art may practice combining each embodiment as needed, and this falls within the scope of the present inventive concept.

What is claimed is:

1. A semiconductor package, comprising:
a plurality of first semiconductor chips stacked on each other;
a second semiconductor chip including a front surface and disposed on the plurality of first semiconductor chips, wherein the front surface of the second semiconductor chip faces the plurality of first semiconductor chips, and wherein the second semiconductor chip further includes a first dummy pad located on a back surface, opposite to the front surface, of the second semiconductor chip; and
a third semiconductor chip including a front surface and disposed on the back surface of the second semiconductor chip, wherein the front surface of the third semiconductor chip faces the second semiconductor chip, wherein the third semiconductor chip further includes a second dummy pad located on the front surface of the third semiconductor chip,
wherein the first dummy pad is disposed on at least a part of a back surface edge region that is adjacent to a side surface of the second semiconductor chip,
wherein the second dummy pad is disposed on at least a part of a front surface edge region that is adjacent to a side surface of the third semiconductor chip, and
wherein the first dummy pad and the second dummy pad are bonded to each other.

2. The semiconductor package of claim 1, wherein:
the first dummy pad is of a plurality of first dummy pads,
the plurality of first dummy pads continuously extend along the back surface edge region of the second semiconductor chip,
the second dummy pad is of a plurality of second dummy pads, and
the plurality of second dummy pads continuously extend along the front surface edge region of the third semiconductor chip.

3. The semiconductor package of claim 1, wherein:
the first dummy pad is of a plurality of first dummy pads,
the plurality of first dummy pads are arranged along the back surface edge region of the second semiconductor chip,
the second dummy pad is of a plurality of second dummy pads, and
the plurality of second dummy pads are arranged along the front surface edge region of the third semiconductor chip.

4. The semiconductor package of claim 1, wherein:
the first dummy pad is of a plurality of first dummy pads,
the plurality of first dummy pads are respectively disposed in a corner region of the back surface edge region that is adjacent to a corner formed by two side surfaces of the second semiconductor chip,
the second dummy pad is of a plurality of second dummy pads, and
the plurality of second dummy pads are respectively disposed in a corner region of the front surface edge region that is adjacent to a corner formed by two side surfaces of the third semiconductor chip.

5. The semiconductor package of claim 1, wherein:
the first dummy pad is of a plurality of first dummy pads,
the plurality of first dummy pads are continuously disposed along regions that are adjacent to two side surfaces, which face each other, of the second semiconductor chip,
the second dummy pad is of a plurality of second dummy pads, and
the plurality of second dummy pads are continuously disposed along regions adjacent to two side surfaces, which face each other, of the third semiconductor chip.

6. The semiconductor package of claim 1, wherein:
the second semiconductor chip further comprises a first insulating layer disposed on a side surface of the first dummy pad,
the third semiconductor chip further comprises a second insulating layer disposed on a side surface of the second dummy pad, and
the first insulating layer and the second insulating layer are bonded to each other.

7. The semiconductor package of claim 1, wherein:
the second semiconductor chip comprises a first connection pad located on the front surface thereof, a second connection pad located on the back surface thereof and spaced apart from the first dummy pad, and a first through via electrically connecting the first connection pad and the second connection pad to each other,
the third semiconductor chip further comprises a third connection pad located on the front surface thereof and spaced apart from the second dummy pad, and
the second connection pad and the third connection pad are bonded to each other.

8. The semiconductor package of claim 7, wherein:
each of the plurality of first semiconductor chips comprises a fourth connection pad located on a front surface of each of the plurality of first semiconductor chips, a fifth connection pad located on a back surface opposite to the front surface of each of the plurality of first semiconductor chips, and a second through via electrically connecting the fourth connection pad and the fifth connection pad to each other, and
the fourth connection pad of a first first semiconductor chip of the plurality of first first semiconductor chips is bonded to the fifth connection pad of a second first semiconductor chip of the plurality of first semiconductor chips.

9. The semiconductor package of claim 1, wherein:
the third semiconductor chip is a dummy chip,
a thickness of the third semiconductor chip is larger than each of a thickness of each of the plurality of first semiconductor chips and a thickness of the second semiconductor chip.

10. The semiconductor package of claim 9, wherein:
the second semiconductor chip is a dummy chip.

11. The semiconductor package of claim 1, further comprising:
a molding material for molding the plurality of first semiconductor chips, the second semiconductor chip, and the third semiconductor chip.

12. The semiconductor package of claim 11, wherein:
a back surface of the third semiconductor chip, which is opposite to the front surface of the third semiconductor chip, is exposed by the molding material.

13. A semiconductor package, comprising:
a first semiconductor chip including a first dummy pad located on a back surface thereof; and
a plurality of second semiconductor chips disposed on a back surface of the first semiconductor chip so that each front surface of each of the plurality of second semiconductor chips faces the first semiconductor chip,
wherein a lowermost second semiconductor chip, which is disposed at the lowest position among the plurality of second semiconductor chips, includes a second dummy pad located on the front surface of the second semiconductor chip,
wherein the second dummy pad is disposed on at least a part of a front surface edge region that is adjacent to a side surface of the lowermost second semiconductor chip, and
wherein the first dummy pad is bonded to the second dummy pad by overlapping each other.

14. The semiconductor package of claim 13, wherein:
the width of the first semiconductor chip is wider than the width of the lowermost second semiconductor chip.

15. The semiconductor package of claim 13, wherein:
the first semiconductor chip is a logic chip, and
the lowermost second semiconductor chip is a high bandwidth memory chip.

16. The semiconductor package of claim 13, wherein:
the first semiconductor chip further comprises a first insulating layer disposed on a side surface of the first dummy pad,
the lowermost second semiconductor chip further comprises a second insulating layer disposed on a side surface of the second dummy pad, and
the first insulating layer and the second insulating layer are bonded to each other.

17. The semiconductor package of claim 13, wherein:
the first semiconductor chip comprises a first connection pad located on a front surface of the first semiconductor chip, which is opposite to the back surface of the first semiconductor chip, a second connection pad located on the back surface of the first semiconductor chip and spaced apart from the first dummy pad, and a first through via electrically connecting the first connection pad and the second connection pad to each other,
each of the plurality of second semiconductor chips comprises a third connection pad located on the front surface of each of the plurality of second semiconductor chips, a fourth connection pad disposed on a back surface of each of the plurality of second semiconductor chips, and a second through via electrically connecting the third connection pad and the fourth connection pad to each other, and
the second connection pad of the first semiconductor chip and the third connection pad of the lowermost second semiconductor chip are bonded to each other.

18. The semiconductor package of claim 17, wherein:
the third connection pad of a first second semiconductor chip of the plurality of second semiconductor chips is bonded to the fourth connection pad of a second second semiconductor chip of the plurality of second semiconductor chips.

19. The semiconductor package of claim 13, further comprising:
a molding material disposed on the first semiconductor chip to mold the plurality of second semiconductor chips.

20. A semiconductor package, comprising:
a first semiconductor chip having opposing front and back surfaces, and comprising a first connection pad located on the front surface thereof, a second connection pad and a first dummy pad located on the back surface thereof and spaced apart from each other, and a first through via electrically connecting the first connection pad and the second connection pad to each other; and
a second semiconductor chip including a front surface and disposed on the back surface of the first semiconductor chip, wherein the front surface of the second semiconductor chip faces the first semiconductor chip, and wherein the second semiconductor chip further includes a third connection pad and a second dummy pad spaced apart from each other on the front surface of the second semiconductor chip,
wherein the first dummy pad is disposed on at least a part of a back surface edge region that is adjacent to a side surface of the first semiconductor chip,
wherein the second dummy pad is disposed on at least a part of a front surface edge region that is adjacent to a side surface of the second semiconductor chip,
wherein the first dummy pad and the second dummy pad are bonded to each other, and
wherein the second connection pad and the third connection pad are bonded to each other.
